(19) United States
(12) Patent Application Publication
(10) Pub. No.: US 2025/0181926 A1
(43) Pub. Date: Jun. 5, 2025

(54) METHOD FOR CONSTRUCTING INTELLIGENT COMPUTATION ENGINE OF ARTIFICIAL INTELLIGENCE CROSS-PLATFORM MODEL ON BASIS OF KNOWLEDGE SELF-EVOLUTION

(71) Applicant: NANJING UNIVERSITY OF POSTS AND TELECOMMUNICATIONS, Jiangsu (CN)

(72) Inventors: Haigen YANG, Jiangsu (CN); Donghuang LIN, Jiangsu (CN); Cong WANG, Jiangsu (CN); Fanyu ZENG, Jiangsu (CN); Erhan DAI, Jiangsu (CN); Jixin LIU, Jiangsu (CN); Yan GE, Jiangsu (CN)

(73) Assignee: NANJING UNIVERSITY OF POSTS AND TELECOMMUNICATIONS, Jiangsu (CN)

(21) Appl. No.: 18/839,733

(22) PCT Filed: Oct. 11, 2023
(86) PCT No.: PCT/CN2023/124030

§ 371 Date: Aug. 20, 2024

(30) Foreign Application Priority Data
Nov. 30, 2022 (CN) 202211517991.1

(51) Int. Cl. G06N 3/092

(52) U.S. Cl. CPC G06N 3/092

(57) ABSTRACT

The present invention discloses a method for constructing an intelligent computation engine of an artificial intelligence cross-platform model based on knowledge self-evolution. The method comprises: determining source and target moments; dividing a discrete manufacturing system data set; initializing a dynamic discrete manufacturing system model; preprocessing data and constructing a task pool; constructing a meta learning framework; migrating a trained neural network to new tasks; iterating until convergence and storing model parameters; and testing in a new environment. This invention shortens the convergence time of model parameters, significantly benefiting the training of dynamic discrete manufacturing models subject to temporal disturbances in actual production.

### TECHNICAL FIELD

The present invention relates to the field of computer data science and technology, and particularly relates to a method for constructing an intelligent computation engine of an artificial intelligence cross-platform model on the basis of knowledge self-evolution.

### BACKGROUND

With the advancement of science and technology and rising demands of the people amid economic globalization, the discrete manufacturing has undergone tremendous changes, and emergencies such as rush orders, cancellation of orders, personalized customization, equipment failures and material coordination have made the production process complex and variable. However, the existing discrete manufacturing systems are hard to be used in dynamic complex scenarios and often require manual intervention. Being trained in specific static scenarios, these existing systems are difficult to cope with the frequent changes in manufacturing information during actual production. Dynamic parameters or system model structures of a workshop system often change due to changes in the actual operating conditions, as well as internal and external conditions of the workshop. Therefore, there is an urgent need for a knowledge self-evolution technology that enables a discrete manufacturing model to evolve over time, adapt to current dynamic scenarios, and realize a truly intelligent and dynamic discrete manufacturing system.

### SUMMARY

The present invention provides a method for constructing an intelligent computation engine of an artificial intelligence cross-platform model on the basis of knowledge self-evolution, which can shorten the time for the convergence of model parameters, and the present invention has great application value for the training of a dynamic discrete manufacturing model, which is disturbed with time in actual production.

In order to solve the above technical problem, the present invention provides a method for constructing intelligent computation engine of artificial intelligence cross-platform model on basis of knowledge self-evolution, including following steps:
step 1. determining a source moment and a target moment; and dividing a discrete manufacturing system data set at a certain moment into a plurality of data sets according to a division rule and on the basis of artificial experience:
step 2. initializing a dynamic discrete manufacturing system model;
step 3: preprocessing data to construct a task pool, where a part of the data is used to train a source model, and the other part of the data is used to train a target neural network;
step 4. constructing a meta learning framework, which includes training the meta learning model and quickly adjusting the target neural network, such that rapid migration among a plurality of tasks is realized;
step 5. changing the target moment, and quickly migrating a trained neural network to a new task by using the meta learning framework;
step 6: iterating the step 5 until the dynamic discrete manufacturing system model converges, and storing the model parameters after convergence; and
step 7. using the dynamic discrete manufacturing system model for a new environment task, and testing the performance of the dynamic discrete manufacturing system model.

Preferably, in the step 1, determining a source moment and a target moment; and dividing a discrete manufacturing system data set at a certain moment into a plurality of data sets according to a division rule and on the basis of artificial experience specifically includes:
step 11. selecting the source moment s and the target moment t, and inputting discrete manufacturing data of the two time periods; and
step 12. dividing the data sets of the two time periods into optimal Nₛ and Nₜ static discrete manufacturing data sets according to the division rule such as equal division, production cost or product quantity and on the basis of artificial experience.

Preferably, in the step 2, initializing a dynamic discrete manufacturing system model specifically includes:
step 21. selecting an appropriate deep reinforcement learning neural network Q based on a deep reinforcement learning algorithm, and initializing a parameter θ of the dynamic discrete manufacturing system model; and
step 22. defining two hyperparameters α and β of a meta learning algorithm, and determining a specific value after a plurality of experiments.

Preferably, in the step 3, preprocessing data to construct a task pool, where a part of the data is used to train a source model, and the other part of the data is used to train a target neural network specifically includes:
step 31: according to the data divided in the step 12, Nₛ categories at the source moment are called meta-train classes, and are used to train a meta learning model Qₛ. which represents a static model applicable to a current moment and operating conditions; and Nₜ categories at the target moment are called meta-test classes, and are used to a target model Qₜ, which represents the dynamic discrete manufacturing system model applicable to the new moment and new operating conditions after dynamic parameters are adjusted;
step 32: setting a task extraction method to M way-K shot, and constructing a data set for training the meta learning model; and selecting Mₛ categories from the meta-train classes, selecting Lₛ samples (Lₛ>Kₛ) for each of the categories to form a task Tₛ. where Kₛ samples are selected from each of the categories and taken as a training set of a current task, which is called a support set, remaining Mₛ*(Lₛ−Kₛ) samples are taken as a test set of the current task, which is called a query set; and a task is repeatedly and randomly extracted from the meta—train classes to form a task pool composed of a plurality of T, and distribution of the task pool is defined as p(Tₛ); and
step 33: constructing a data set for training the target model; and selecting Mₜ categories from meta—test classes, selecting Lₜ samples (Lₜ>Kₜ) for each of the categories to form a task Tₜ, where Kₜ samples are selected from each of the categories and taken as a training set of a current task, which is called a support set, remaining Mₜ*(Lₜ−Kₜ) samples are taken as a test set of the current task, which is called a query set; and a task is repeatedly and randomly extracted from the meta—test classes to form a task pool composed of a plurality of T, and distribution of the task pool is defined as p(Tₜ).

Preferably, in the step 4, constructing a meta learning framework, which includes training the meta learning model and quickly adjusting the target neural network, such that rapid migration among a plurality of tasks is realized, which specifically includes following steps:
step 41. training the meta learning model Qₛ, specifically including following sub-steps:
(a) randomly initializing a model parameter θs of the meta learning model Qₛ;
(b) randomly sampling nₛ tasks T from the task pool to form a batch, where each of the tasks Tᵢ(i=1,2,3 . . . , nₛ) satisfies distribution of Tᵢ˜p(Tₛ);
(c) calculating a gradient ∇_{θ}_{ₛ}L_{T}_{ᵢ}(f_{θ}_{ₛ}) of the model parameter θₛ by using the support set in a certain task Tᵢ of the batch, with a formula for updating the model parameter θₛ as follows:

$${θ}_{s i}^{′} = {θ}_{s} - α {∇}_{{θ}_{s}} {L}_{{T}_{i}} ( {f}_{{θ}_{s}} )$$

in the formula, θ′ₛᵢ is a parameter of the meta learning model Qₛ updated based on Tᵢ, and ∇_{θ}_{ₛ}L_{T}_{ᵢ}(f_{θ}_{ₛ}) is a loss gradient function of θₛ calculated based on Tᵢ;
(d) repeating the step (c) based on every task in the batch for nₐ times, such that a first updating of the gradient is completed, and the updated parameter θₛ is obtained;
(e) performing a second updating of the gradient: calculating a loss gradient of θₛ by using the query set in each of the tasks Tᵢ in the batch, and then calculating a sum of losses of the batch, and updating the gradient by using the sum of losses, with a formula updating the gradient as follows:

$${θ}_{s i}^{′} = {θ}_{s} - α {∇}_{{θ}_{s}} {\sum }_{{T}_{i} ∼ p ( {T}_{s} )} {L}_{{T}_{i}} ( {f}_{{θ}_{s}} )$$

in this way, updating the second gradient is completed, and training of the meta learning model on the batch is ended;
(f) returning to the step (b), and re-sampling to form a next batch;
step 42. obtaining an initialized parameter θₛ of the meta learning model Qₛ after the training is completed, dynamically adjusting the model parameters according to the data set at the target moment to have the target model adapted to new internal and external production environments, and the training of the target model Qₜ specifically includes following steps:
(g) initializing the model parameter of the target model Qₜ, and assigning Qₜ to the model parameter Qₛ; that is, θₜ=θₛ;
(h) randomly sampling nₜ tasks T from the task pool, where each of the tasks Tᵢ(i=1,2,3 . . . , n) satisfies distribution of Tᵢ˜p(Tₜ);
(i) calculating a gradient ∇_{θ}_{ₜ}L_{T}_{ᵢ}(f_{θ}_{ₜ}) of the model parameter θₜ by using the support set in a certain task Tᵢ of the batch, with a formula for updating the model parameter θₜ as follows:

$${θ}_{t i}^{′} = {θ}_{t} - α {∇}_{{θ}_{t}} {L}_{{T}_{i}} ( {f}_{{θ}_{t}} )$$

in the formula, θ′ₜᵢ is a parameter of the updated target model Qₜ based on Tᵢ; and
(j) employing the formula in the step (i) to the parameter θₜ initialized in the step (g) based on each of the tasks randomly extracted in the step (h) to obtain nₜ updated parameters θ′ₜᵢ, and averaging the updated parameters to obtain final model parameters, with a formula as follows:

$${θ}_{t}^{′} = {\sum }_{i = 1}^{{n}_{t}} {θ}_{t i}^{′}$$

the above is a training process of the target model Qₜ, a neural network model Qₜ applicable to the target moment t is finally obtained, and dynamic adjustment of parameters and rapid migration of the dynamic discrete manufacturing system model are implemented.

Preferably, in the step 5, changing the target moment, and quickly migrating a trained neural network to a new task by using the meta learning framework specifically include following steps:
step 51. taking the trained target neural network model Qₜ as the source model, and a next moment t+1 as a new target moment, and then quickly migrating the neural network model from the target moment t to the moment t+1;
step 52. performing data preprocessing according to the step 3 to construct the task pool; and
step 53. obtaining a parameter θₜ₊₁ of a new target neural network Qₜ₊₁ according to the step 4.

Preferably, in the step 6: iterating the step 5 until the dynamic discrete manufacturing system model converges, and storing the model parameters after convergence specifically include following steps:
step 61: iterating the step 5 to continuous obtain neural network models Qₜ, Qₜ₊₁, Qₜ₊₂ . . . at next moments until the model parameters converge, indicating that the dynamic discrete manufacturing system model can adapt well to production environments with different operating conditions in different time periods, and can output an optimal decision, regardless of internal and external conditions; and
step 62: storing the model parameters after the model converges to obtain the final dynamic discrete manufacturing system model.

Preferably, in the step 7, using the dynamic discrete manufacturing system model for a new environment task, and testing the performance of the dynamic discrete manufacturing system model, specifically: when the dynamic discrete manufacturing system model can output a scheduling strategy well in a new environment, and has higher efficiency than the original system, it indicates the results meet the expectation, and the training is completed; and going back to the step 1 to perform the training again when the results fail to meet the expectation.

Beneficial effects of the present invention are as follows: the present invention involves few small calculations and good generalization performance. Based on a training set composed of a small number of samples of different types, the present invention employs the meta learning framework to achieve the learning of common features across multiple categories, thereby improving the generalization performance of the dynamic discrete manufacturing model. The model parameters converge quickly and exhibit strong transferability. By loading the optimized parameters trained by meta-learning as initialization parameters for a new task, the present invention can complete the model parameters for the discrete manufacturing model at a new moment only through a few training steps, facilitating rapid task migration, and the more similar the new task is to the original task, the less time is required. Compared with randomly initializing parameters or loading the existing network model parameters, the algorithm enables rapid fine-tuning of the neural network, and shortens the time for the convergence of the model parameters, and the present invention has great application value for the training of a dynamic discrete manufacturing model, which is disturbed with time in actual production.

### BRIEF DESCRIPTION OF THE DRAWINGS

FIG. 1 is a schematic flowchart of a method according to the present invention.

FIG. 2 is a structural schematic diagram of a meta learning framework according to the present invention.

### DETAILED DESCRIPTIONS OF THE EMBODIMENTS

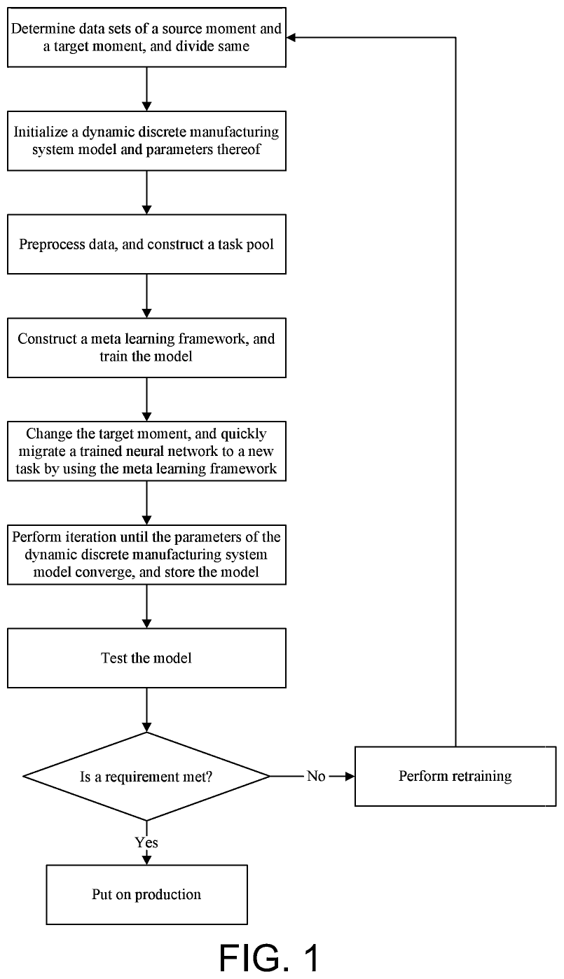

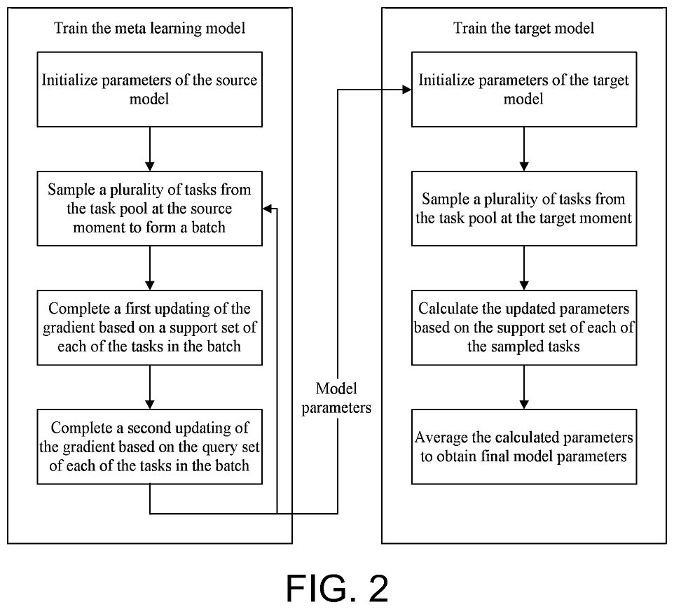

As shown in FIGS. 1-2, a method for constructing intelligent computation engine of artificial intelligence cross-platform model on basis of knowledge self-evolution is provided, including following steps:
step 1. determining a source moment and a target moment; dividing a discrete manufacturing system data set at a certain moment into a plurality of data sets according to a division rule and on the basis of artificial experience; selecting data sets of two time periods from dynamic discrete manufacturing data, the data sets of the two time periods represent different workshop operating conditions and internal and external conditions, dynamic parameters of a workshop system change accordingly, such that the workshop system needs to realize self-evolution to adjust the dynamic parameters by itself, so as to adapt to complex and changeable workshop production conditions. The two data sets are called data sets at the source moment and the target moment respectively, the data set at the source moment represents data used to train a static discrete manufacturing production model, the data set at the target moment represents data after the workshop operating conditions and the internal and external conditions have changed, indicating that the dynamic discrete manufacturing system model is applicable to a new moment after the dynamic parameters are adjusted, and adaptive adjustment of the dynamic discrete manufacturing system model is achieved. Next, the discrete manufacturing system data set at the source moment is divided into a plurality of data sets according to the division rule and on the basis of artificial experience (completely dividing the data set equally, dividing the data set into a plurality of data sets with a same corresponding cost according to a production cost or dividing the data set according to a number of produced products).

### Specifically:

step 11. selecting the source moment s and the target moment t, and inputting discrete manufacturing data of the two time periods; and
step 12. dividing the data sets of the two time periods into optimal Nₛ and Nₜ static discrete manufacturing data sets according to the division rule such as equal division, production cost or product quantity and on the basis of artificial experience.

Step 2. initializing the dynamic discrete manufacturing system model, specifically:
step 21. selecting an appropriate deep reinforcement learning neural network Q based on a deep reinforcement learning algorithm, and initializing a parameter θ of the dynamic discrete manufacturing system model;
step 22. defining two hyperparameters α and β of a meta learning algorithm, and determining a specific value after a plurality of experiments.

Step 3: preprocessing data to construct a task pool, where a part of the data is used to train a source model, and the other part of the data is used to train a target neural network; and specifically includes following steps:
step 31: according to the data divided in the step 12, Nₛ categories at the source moment are called meta—train classes, and are used to train a meta learning model Qₛ. which represents a static model applicable to a current moment and operating conditions; and Nₜ categories at the target moment are called meta-test classes, and are used to a target model Qₜ, which represents the dynamic discrete manufacturing system model applicable to the new moment and new operating conditions after dynamic parameters are adjusted;
step 32: setting a task extraction method to M way-K shot, and constructing a data set for training the meta learning model; and selecting Mₛ categories from the meta-train classes, selecting Lₛ samples (Lₛ>Kₛ) for each of the categories to form a task Tₛ, where Kₛ samples are selected from each of the categories and taken as a training set of a current task, which is called a support set, remaining Mₛ*(Lₛ−Kₛ) samples are taken as a test set of the current task, which is called a query set; and a task is repeatedly and randomly extracted from the meta—train classes to form a task pool composed of a plurality of T. and distribution of the task pool is defined as p(Tₛ); and
step 33: constructing a data set for training the target model; and selecting Mₜ categories from meta—test classes, selecting Lₜ samples (Lₜ>Kₜ) for each of the categories to form a task Tₜ, where Kₜ samples are selected from each of the categories and taken as a training set of a current task, which is called a support set, remaining Mₜ*(Lₜ−Kₜ) samples are taken as a test set of the current task, which is called a query set; and a task is repeatedly and randomly extracted from the meta—test classes to form a task pool composed of a plurality of T, and distribution of the task pool is defined as p(Tₜ).

Step 4. constructing a meta learning framework, which includes training the meta learning model and quickly adjusting the target neural network, such that rapid migration among a plurality of tasks is realized, specifically including following steps:
step 41. training the meta learning model Qₛ, specifically including following steps:
(a) randomly initializing a model parameter θₛ of the meta learning model Qₛ;
(b) randomly sampling nₛ tasks T from the task pool to form a batch, where each of the tasks Tᵢ(i=1,2,3 . . . , nₛ) satisfies distribution of Tᵢ˜p(Tₛ);
(c) calculating a gradient ∇_{θ}_{ₛ}L_{T}_{ᵢ}(f_{θ}_{ₛ}) of the model parameter θₛ by using the support set in a certain task Tᵢ of the batch, with a formula for updating the model parameter θₛ as follows:

$${θ}_{s i}^{′} = {θ}_{s} - α {∇}_{{θ}_{s}} {L}_{{T}_{i}} ( {f}_{{θ}_{s}} )$$

in the formula, θ′ₛᵢ is a parameter of the updated meta learning model Qₛ based on Tᵢ, and ∇_{θ}_{ₛ}L_{T}_{ᵢ}(f_{θ}_{ₛ}) is a loss gradient function of θₛ calculated based on Tᵢ;
(d) repeating the step (c) based on every task in the batch for n_{α} times, such that a first updating of the gradient is completed, and the updated parameter θₛ is obtained;
(e) performing a second updating of the gradient: calculating a loss gradient of θₛ by using the query set in each of the tasks Tᵢ in the batch, and then calculating a sum of losses of the batch, and updating the gradient by using the sum of losses, with a formula updating the gradient as follows:

$${θ}_{s i}^{′} = {θ}_{s} - α {∇}_{{θ}_{s}} {\sum }_{{T}_{i} ∼ p ( {T}_{s} )} {L}_{{T}_{i}} ( {f}_{{θ}_{s}} )$$

in this way, updating the second gradient is completed, and training of the meta learning model on the batch is ended;
(f) returning to the step (b), and re-sampling to form a next batch;
step 42. obtaining an initialized parameter θₛ of the meta learning model Qₛ after the training is completed, dynamically adjusting the model parameters according to the data set at the target moment to have the target model adapted to new internal and external production environments, and the training of the target model Qₜ specifically includes following steps:
(g) initializing the model parameter of the target model Qₜ, and assigning Qₜ to the model parameter Qₛ; that is, θₜ=θₛ;
(h) randomly sampling nₜ tasks T from the task pool, where each of the tasks Tᵢ(i=1,2,3 . . . , n) satisfies distribution of Tᵢ˜p(Tₜ);
(i) calculating a gradient ∇_{θ}_{ₜ}L_{T}_{ᵢ}(f_{θ}_{ₜ}) of the model parameter θₜ by using the support set in a certain task Tᵢ of the batch, with a formula for updating the model parameter θₜ as follows:

$${θ}_{t i}^{′} = {θ}_{t} - α {∇}_{{θ}_{t}} {L}_{{T}_{i}} ( {f}_{{θ}_{t}} )$$

in the formula, θ′ₜᵢ is a parameter of the updated target model Qₜ based on Tᵢ; and
(j) employing the formula in the step (i) to the parameter θₜ initialized in the step (g) based on each of the tasks randomly extracted in the step (h) to obtain nₜ updated parameters θ′ₜᵢ, and averaging the updated parameters to obtain final model parameters, with a formula as follows:

$${θ}_{t}^{′} = {\sum }_{i = 1}^{{n}_{t}} {θ}_{t i}^{′}$$

the above is a training process of the target model Qₜ, a neural network model Qₜ applicable to the target moment t is finally obtained, and dynamic adjustment of parameters and rapid migration of the dynamic discrete manufacturing system model are implemented.

Step 5. changing the target moment, and quickly migrating a trained neural network to a new task by using the meta learning framework, specifically including following steps:
step 51. taking the trained target neural network model Qₜ as the source model, and a next moment t+1 as a new target moment, and dividing the data sets of the two time periods according to the step 12; and then quickly migrating the neural network model from the target moment t to the moment t+1;
step 52. performing data preprocessing according to the step 3 to construct the task pool; and
step 53. obtaining a parameter θₜ₊₁ of a new target neural network Qₜ₊₁ according to the step 4.

Step 6: iterating the step 5 until the dynamic discrete manufacturing system model converges, and storing the model parameters after convergence; specifically including following steps:
step 61: iterating the step 5 to continuous obtain neural network models Qₜ, Qₜ₊₁, Qₜ₊₂ . . . at next moments until the model parameters converge, indicating that the dynamic discrete manufacturing system model can adapt well to production environments with different operating conditions in different time periods, and can output an optimal decision, regardless of internal and external conditions; and
step 62: storing the model parameters after the model converges to obtain the final dynamic discrete manufacturing system model.

Step 7. using the dynamic discrete manufacturing system model for a new environment task, and testing the performance of the dynamic discrete manufacturing system model, specifically: when the dynamic discrete manufacturing system model can output a scheduling strategy well in a new environment, and has higher efficiency than the original system, it indicates the results meet the expectation, and the training is completed; and going back to the step 1 to perform the training again when the results fail to meet the expectation.

1. A method for constructing an intelligent computation engine of an artificial intelligence cross-platform model on the basis of knowledge self-evolution, comprising following steps:
step 1, determining a source moment and a target moment; and dividing a discrete manufacturing system data set at a certain moment into a plurality of data sets according to a division rule and on the basis of artificial experience;
step 2, initializing a dynamic discrete manufacturing system model;
step 3, preprocessing data to construct a task pool, wherein a part of the data is used to train a source model, and the other part of the data is used to train a target neural network;
step 4, constructing a meta learning framework, which comprises training the meta learning model and quickly adjusting the target neural network, such that rapid migration among a plurality of tasks is realized;
step 5, changing the target moment, and quickly migrating a trained neural network to a new task by using the meta learning framework;
step 6, iterating the step 5 until the dynamic discrete manufacturing system model converges, and storing the model parameters after convergence; and
step 7, using the dynamic discrete manufacturing system model for a new environment task, and testing the performance of the dynamic discrete manufacturing system model.

2. The method for constructing an intelligent computation engine of an artificial intelligence cross-platform model on the basis of knowledge self-evolution according to claim 1, wherein in the step 1, determining a source moment and a target moment; and dividing a discrete manufacturing system data set at a certain moment into a plurality of data sets according to a division rule and on the basis of artificial experience comprise following steps:
step 11, selecting the source moment s and the target moment t, and inputting discrete manufacturing data of the two time periods; and
step 12, dividing the data sets of the two time periods into optimal Nₛ and Nₜ static discrete manufacturing data sets according to the division rule such as equal division, production cost or product quantity and on the basis of artificial experience.

3. The method for constructing an intelligent computation engine of an artificial intelligence cross-platform model on the basis of knowledge self-evolution according to claim 1, wherein in the step 2, initializing a dynamic discrete manufacturing system model comprises following steps:
step 21, selecting an appropriate deep reinforcement learning neural network Q based on a deep reinforcement learning algorithm, and initializing a parameter θ of the dynamic discrete manufacturing system model; and
step 22, defining two hyperparameters α and β of a meta learning algorithm, and determining a specific value after a plurality of experiments.

4. The method for constructing an intelligent computation engine of an artificial intelligence cross-platform model on the basis of knowledge self-evolution according to claim 1, wherein in the step 3, preprocessing data to construct a task pool, wherein a part of the data is used to train a source model, and the other part of the data is used to train a target neural network comprises following steps:
step 31, according to the data divided in the step 12, Nₛ categories at the source moment are called meta—train classes and are used to train a meta learning model Qₛ, which represents a static model applicable to a current moment and operating conditions; and Nₜ categories at the target moment are called meta—test classes, and are used to a target model Qₜ, which represents the dynamic discrete manufacturing system model applicable to the new moment and new operating conditions after dynamic parameters are adjusted;
step 32, setting a task extraction method to M way-K shot, and constructing a data set for training the meta learning model; and selecting Mₛ categories from the meta—train classes, selecting Lₛ samples (Lₛ>Kₛ) for each of the categories to form a task Tₛ, wherein Kₛ samples are selected from each of the categories and taken as a training set of a current task, which is called a support set, remaining Mₛ*(Lₛ−Kₛ) samples are taken as a test set of the current task, which is called a query set; and a task is repeatedly and randomly extracted from the meta—train classes to form a task pool composed of a plurality of T, and distribution of the task pool is defined as p(Tₛ); and
step 33, constructing a data set for training the target model; and selecting Mₜ categories from the meta—test classes, selecting Lₜ samples (Lₜ>Kₜ) for each of the categories to form a task Tₜ, wherein Kₜ samples are selected from each of the categories and taken as a training set of a current task, which is called a support set, remaining Mₜ*(Lₜ−Kₜ) samples are taken as a test set of the current task, which is called a query set; and task is repeatedly and randomly extracted from the meta—test classes to form a task pool composed of a plurality of T, and distribution of the task pool is defined as p(Tₜ).

5. The method for constructing an intelligent computation engine of an artificial intelligence cross-platform model on the basis of knowledge self-evolution according to claim 1, wherein in the step 4, constructing a meta learning framework, which comprises training the meta learning model and quickly adjusting the target neural network, such that rapid migration among a plurality of tasks is realized, which comprises following steps:
step 41, training the meta learning model Qₛ, comprising following sub-steps:
(a) randomly initializing a model parameter θₛ of the meta learning model Qₛ;
(b) randomly sampling nₛ tasks T from the task pool to form a batch, wherein each of the tasks Tᵢ(i=1,2,3 . . . , nₛ) satisfies distribution of Tᵢ˜p(Tₛ);
(c) calculating a gradient ∇_{θ}_{ₛ}L_{T}_{ᵢ}(f_{θ}_{ₛ}) of the model parameter θₛ by using the support set in a certain task Tᵢ of the batch, with a formula for updating the model parameter θₛ as follows:
$${θ}_{s i}^{′} = {θ}_{s} - α {∇}_{{θ}_{s}} {L}_{{T}_{i}} ( {f}_{{θ}_{s}} )$$
in the formula, θ′ₛᵢ is a parameter of the updated meta learning model Qₛ based on Tᵢ, and ∇_{θ}_{ₛ}L_{T}_{ᵢ}(f_{θ}_{ₛ}) is a loss gradient function of θₛ calculated based on Tᵢ;
(d) repeating the step (c) based on every task in the batch for n_{α} times, such that a first updating of the gradient is completed, and the updated parameter θₛ is obtained;
(e) performing a second updating of the gradient: calculating a loss gradient of θₛ by using the query set in each of the tasks Tᵢ in the batch, and then calculating a sum of losses of the batch, and updating the gradient by using the sum of losses, with a formula updating the gradient as follows:
$${θ}_{s i}^{′} = {θ}_{s} - α {∇}_{{θ}_{s}} {\sum }_{{T}_{i} ∼ p ( {T}_{s} )} {L}_{{T}_{i}} ( {f}_{{θ}_{s}} )$$
in this way, updating the second gradient is completed, and training of the meta learning model on the batch is ended;
(f) returning to the step (b), and re-sampling to form a next batch;
step 42, obtaining an initialized parameter θₛ of the meta learning model Qₛ after the training is completed, dynamically adjusting the model parameters according to the data set at the target moment to have the target model adapted to new internal and external production environments, and the training of the target model Qₜ comprises following sub-steps:
(g) initializing the model parameter of the target model Qₜ, and assigning Qₜ to the model parameter Qₛ; that is, θₜ=θₛ;
(h) randomly sampling nₜ tasks T from the task pool, wherein each of the tasks Tᵢ(i=1,2,3 . . . , n) satisfies distribution of Tᵢ˜p(Tₜ);
(i) calculating a gradient ∇θₜL_{T}_{ᵢ}(f_{θ}_{ₜ}) of the model parameter θₜ by using the support set in a certain task Tᵢ of the batch, with a formula for updating the model parameter θₜ as follows:
$${θ}_{t i}^{′} = {θ}_{t} - α {∇}_{{θ}_{t}} {L}_{{T}_{i}} ( {f}_{{θ}_{t}} )$$
in the formula, θ′ₜᵢ is a parameter of the updated target model Qₜ based on Tᵢ; and
(j) employing the formula in the step (i) to the parameter θₜ initialized in the step (g) based on each of the tasks randomly extracted in the step (h) to obtain nₜ updated parameters θ′ₜᵢ, and averaging the updated parameters to obtain final model parameters, with a formula as follows:
$${θ}_{t}^{′} = {\sum }_{i = 1}^{{n}_{t}} {θ}_{t i}^{′}$$
the above is a training process of the target model Qₜ, a neural network model Qₜ applicable to the target moment t is finally obtained, and dynamic adjustment of parameters and rapid migration of the dynamic discrete manufacturing system model are implemented.

6. The method for constructing an intelligent computation engine of an artificial intelligence cross-platform model on the basis of knowledge self-evolution according to claim 1, wherein in the step 5, changing the target moment, and quickly migrating a trained neural network to a new task by using the meta learning framework comprises following steps:
step 51, taking the trained target neural network model Qₜ as the source model, and a next moment t+1 as a new target moment, and then quickly migrating the neural network model from the target moment t to the moment t+1;
step 52, performing data preprocessing according to the step 3 to construct the task pool; and
step 53, obtaining a parameter θₜ₊₁ of a new target neural network Qₜ₊₁ according to the step 4.

7. The method for constructing an intelligent computation engine of an artificial intelligence cross-platform model on the basis of knowledge self-evolution according to claim 1, wherein in the step 6, iterating the step 5 until the dynamic discrete manufacturing system model converges, and storing the model parameters after convergence comprises following steps:
step 61, iterating the step 5 to continuous obtain neural network models Qₜ, Qₜ₊₁, Qₜ₊₂ . . . at next moments until the model parameters converge, indicating that the dynamic discrete manufacturing system model is adapted well to production environments with different operating conditions in different time periods, and is output an optimal decision, regardless of internal and external conditions; and
step 62, storing the model parameters after the model converges to obtain the final dynamic discrete manufacturing system model.

8. The method for constructing an intelligent computation engine of an artificial intelligence cross-platform model on the basis of knowledge self-evolution according to claim 1, wherein in the step 7, using the dynamic discrete manufacturing system model for a new environment task, and testing the performance of the dynamic discrete manufacturing system model, comprising: when the dynamic discrete manufacturing system model is output a scheduling strategy well in a new environment, and has higher efficiency than the original system, it indicates the results meet the expectation, and the training is completed; and going back to the step 1 to perform the training again when the results fail to meet the expectation.
